(19) United States
(12) Patent Application Publication
(10) Pub. No.: US 2007/0144440 A1
(43) Pub. Date: Jun. 28, 2007

(54) Plasma producing method and apparatus as well as plasma processing apparatus

(75) Inventors: Hitoshi Yoneda, Kyoto-shi (JP); Hiroshige Deguchi, Kyoto-shi (JP); Kenji Kato, Kyoto-shi (JP); Yuichi Setsuhara, Osaka (JP)

Correspondence Address: RADER FISHMAN & GRAUER PLLC, LION BUILDING, 1233 20TH STREET N.W., SUITE 501, WASHINGTON, DC, 20036, US

(73) Assignee: NISSIN ELECTRIC CO., LTD., Kyoto-Shi (JP)

(21) Appl. No.: 11/586,504

(22) Filed: Oct. 26, 2006

(30) Foreign Application Priority Data
Oct. 27, 2005 (JP) 2005-312670

(51) Int. Cl. C23C 16/00

(52) U.S. Cl. 118/723 I

(57) ABSTRACT

Plasma producing method and apparatus as well as plasma processing apparatus utilizing the plasma producing apparatus wherein a plurality of high-frequency antennas are arranged in a plasma producing chamber, and a high-frequency power supplied from a high-frequency power supply device (including a power source, a matching box and the like) is applied to a gas in the chamber from the antennas to produce inductively coupled plasma. At least some of the plurality of high-frequency antennas are arranged in a fashion of such parallel arrangement that the antennas successively neighbor to each other and each of the antennas is opposed to the neighboring antenna. The high-frequency power supply device supplies the high-frequency power to each antenna from terminals of the antennas on the same side.

### CROSS-REFERENCE TO RELATED APPLICATION

This invention is based on Japanese Patent Application No. 2005-312670 filed in Japan on Oct. 27, 2005, the entire content of which is hereby incorporated by reference.

### BACKGROUND OF THE INVENTION

1. Field of the Invention

The invention relates to a plasma producing method and apparatus for producing gas plasma as well as a plasma processing apparatus using the plasma producing apparatus, i.e., a plasma processing apparatus effecting intended processing on a work to be processed in plasma.

2. Description of the Related Art

Plasma is used, e.g., in plasma CVD method and apparatus forming a film in plasma, method and apparatus forming a film by effecting sputtering on a sputter target in plasma, method and apparatus performing etching in plasma, and method, apparatus and the like used for performing ion implantation or ion doping by extracting ions from plasma. Further, the plasma is used in various apparatuses utilizing the plasma such as apparatuses producing various semiconductor devices (e.g., thin-film transistors used in liquid crystal displays or the like), material substrates thereof or the like by using the foregoing methods and/or apparatuses.

Various types of plasma producing methods and apparatuses have been known and, for example, such types have been known that produce capasitively coupled plasma, produce inductively coupled plasma or ECR (Electron Cyclotron Resonance) plasma or produce microwave plasma.

Among them, the plasma producing apparatus producing the inductively coupled plasma are configured to obtain plasma of extremely high density and uniformity in a plasma producing chamber and, for this purpose, has a high-frequency antenna for the plasma producing chamber for producing the inductively coupled plasma by applying a high-frequency power from the high-frequency antenna to a gas in the chamber. More specifically, the high-frequency power is supplied to the high-frequency antenna to generate an induction electromagnetic field in the plasma producing chamber, and the induction electromagnetic field produces the inductively coupled plasma.

Such high-frequency antenna may be arranged outside the plasma producing chamber, but it is also proposed to arrange it inside the plasma producing chamber for improving use efficiency of the supplied high-frequency power and other purposes.

For example, it is described in JP2004-200233A that high-frequency antennas are arranged inside a plasma producing chamber, and the plurality of high-frequency antennas arranged in the plasma producing chamber are successively and linearly arranged on the same plane, and the neighboring electrodes of the neighboring antennas have the same polarity to uniformize the plasma density distribution and improve the plasma density.

However, when the high-frequency antennas are arranged inside the plasma producing chamber, the more the plurality of high-frequency antennas are arranged inside the plasma producing chamber, the higher density plasma can be produced. But, as described in the JP2004-200233A, when the plurality of high-frequency antennas arranged in the plasma producing chamber are successively and linearly arranged on the same plane, the magnetic flux density can not be increased and the plasma density can not be improved despite arrangement of the plurality of antennas.

### SUMMARY OF THE INVENTION

Accordingly, an object of the invention is to provide a plasma producing method in which a plurality of high-frequency antennas are arranged in a plasma producing chamber, and inductively coupled plasma is generated by applying a high-frequency power from the high-frequency antennas to a gas in the plasma producing chamber, and particularly high density plasma according to the number of antennas is produced.

Another object of the invention is to provide a plasma producing apparatus including a plasma producing chamber, a plurality of high-frequency antennas arranged in the plasma producing chamber and a high-frequency power supply device supplying a high-frequency power to the high-frequency antennas, wherein inductively coupled plasma is generated by applying the high-frequency power supplied from the high-frequency power supply device to a gas in the plasma producing chamber from the high-frequency antennas, and particularly high density plasma according to the number of antennas is produced.

A further object of the invention is to provide a plasma processing apparatus that can rapidly perform intended processing on a work to be processed with high density plasma.

The inventors have conducted study for achieving the above objects, and have found the following.

That is, in the structure of arranging a plurality of high-frequency antennas in the plasma producing chamber to produce inductively coupled plasma, when the plurality of high-frequency antennas are arranged in parallel arrangement in which respective neighboring antennas are opposite to each other, and a high-frequency power is supplied to the same side terminals of the antennas such that currents flow through the high-frequency antennas in the same direction, a magnetic flux density corresponding to the plurality of high-frequency antennas can be produced, whereby high density plasma corresponding to the plurality of high frequency antennas can be produced.

Based on the above findings, the present invention provides the following plasma producing method, plasma producing apparatus and plasma processing apparatus.

(1) A Plasma Producing Method

A plasma producing method in which a plurality of high-frequency antennas are arranged in a plasma producing chamber and inductively coupled plasma is generated by applying a high-frequency power from the high-frequency antennas to a gas in the plasma producing chamber, wherein at least some of the high-frequency antennas are arranged in a fashion of such parallel arrangement that the antennas successively neighbor to each other and each of the antennas is opposed to the neighboring antenna, and the high-frequency power is supplied to these high-frequency antennas from terminals of the antennas on the same side such that electric currents flow through the high-frequency antennas in the same direction.

(2) A Plasma Producing Apparatus

A plasma producing apparatus comprising a plasma producing chamber, a plurality of high-frequency antennas arranged in the plasma producing chamber and a high-frequency power supply device supplying a high-frequency power to the high-frequency antennas in which inductively coupled plasma is generated by applying the high-frequency power supplied from the high-frequency power supply device to a gas in the plasma producing chamber from the high-frequency antennas, wherein at least some of the high-frequency antennas are arranged in a fashion of such parallel arrangement that the antennas successively neighbor to each other and each of the antennas is opposed to the neighboring antenna, and the high-frequency power supply device supplies the high-frequency power to the high-frequency antennas, which are arranged in a fashion of such parallel arrangement that the antennas successively neighbor to each other and each of the antennas is opposed to the neighboring antenna, from terminals of the antennas on the same side such that electric currents flow through the antennas in the same direction.

(3) A Plasma Processing Apparatus

A plasma processing apparatus for effecting intended processing on a work to be processed, including a plasma producing apparatus according to the invention.

The foregoing and other objects, features, aspects and advantages of the present invention will become more apparent from the following detailed description when taken in conjunction with the accompanying drawings.

### BRIEF DESCRIPTION OF THE DRAWINGS

FIG. 1 is a view showing an example of a plasma producing apparatus according to the invention.

FIG. 2 is a perspective view of extracts of high-frequency antennas and others of the plasma producing apparatus in FIG. 1.

FIG. 3 is a view showing an example (plasma CVD apparatus) of a plasma processing apparatus according to the invention.

### DESCRIPTION OF THE PREFERRED EMBODIMENTS

A plasma producing method of a preferred embodiment of the invention is a plasma producing method in which a plurality of high-frequency antennas are arranged in a plasma producing chamber, and inductively coupled plasma is produced by applying a high-frequency power to a gas in the plasma producing chamber from the high-frequency antennas.

At least some of the high-frequency antennas are arranged in a fashion of such parallel arrangement that the antennas successively neighbor to each other and each of the antennas is opposed to the neighboring antenna. The high-frequency power is supplied to these high-frequency antennas from terminals of the antennas on the same side such that electric currents flow through the high-frequency antennas in the same direction.

A plasma producing apparatus of a preferred embodiment of the invention has a plasma producing chamber, a plurality of high-frequency antennas arranged in the plasma producing chamber and a high-frequency power supplying device supplying a high-frequency power to the high-frequency antennas, wherein inductively coupled plasma is produced by applying the high-frequency power supplied from the high-frequency power supplying device to a gas in the plasma producing chamber from the high-frequency antennas.

In the plasma producing apparatus, at least some of the high-frequency antennas are arranged in a fashion of such parallel arrangement that the antennas successively neighbor to each other and each of the antennas is opposed to the neighboring antenna.

The high-frequency power supplying device supplies the high-frequency power to the high-frequency antennas arranged in a fashion of such parallel arrangement that the antennas successively neighbor to each other and each of the antennas is opposed to the neighboring antenna from terminals of the antennas on the same side such that electric currents flow through the antennas in the same direction

According to the plasma producing method and apparatus, at least some of the high-frequency antennas arranged in the plasma producing chamber are arranged in a fashion of such parallel arrangement that the antennas successively neighbor to each other and each of the antennas is opposed to the neighboring antenna. The high-frequency power is supplied to these antennas from the terminals thereof on the same side such that currents flow through the antennas in the same direction. Accordingly, high density magnetic flux corresponding to the plurality of antennas can be generated, whereby high density plasma corresponding to the plurality of high-frequency antennas can be produced.

In the plasma producing method and apparatus described above, the high-frequency antenna may be a two-dimensional structure antenna (of a plane structure) that is terminated without circling. For example, the antenna may be formed by bending a linear or belt-like conductor, (e.g., into a U-shaped or nearly U-shaped form).

In the plasma producing method and apparatus described above, the “in a fashion of such parallel arrangement that each of the antennas is opposed to the neighboring antenna” in the “in a fashion of such parallel arrangement that the antennas successively neighbor to each other and each of the antennas is opposed to the neighboring antenna” does not indicate such a state that the neighboring antennas are arranged on the same or substantially the same plane, and successively and linearly neighbor to each other, but indicates that the neighboring antennas are arranged on different planes parallel or substantially parallel to each other, respectively, are opposed to each other and are parallel or substantially parallel to each other. Shifting to a certain extent is allowed provided that the objects of the invention can be achieved.

In the plasma producing method and apparatus described above, all the plurality of high-frequency antennas arranged in the plasma producing chamber may be arranged in a fashion of such parallel arrangement that the antennas successively neighbor to each other and each of the antennas is opposed to the neighboring antenna. The high-frequency power may be supplied to each of these antennas from the terminals thereof on the same side such that currents flow through the antennas in the same direction (in the case of the plasma producing apparatus, the high-frequency power supply device supplies high-frequency power in such way).

In the plasma producing method and apparatus described above, the plurality of high-frequency antennas arranged in the plasma producing chamber may be divided into a plurality of groups. The high-frequency antennas in all or some of the groups including two or more antennas may be arranged in a fashion of such parallel arrangement that the antennas successively neighbor to each other and each of the antennas is opposed to the neighboring antenna, and a high-frequency power may be supplied to each of these antennas from terminals of the antennas on the same side so as to allow currents to flow through the antennas in the same direction (in the case of the plasma producing apparatus, the high-frequency power may be so supplied from the high-frequency power supply device).

In a plasma producing method, a busbar connected to the same side terminals of the plurality of high-frequency antennas may be employed in common with the plurality of high-frequency antennas to supply a high-frequency power to each of the antennas from the terminals of the antennas on the same side. For example, the high-frequency power may be supplied from a high-frequency power source through the busbar via a matching box.

Likewise the high-frequency power supply device in the plasma producing apparatus may include a busbar connected to the same side terminals of the plurality of high-frequency antennas in common with the antennas to supply a high-frequency power. For example, a high-frequency power source may be connected to the busbar via a matching box. In this case, the high-frequency power supply device is inclusive of the busbar, matching box and high-frequency power source.

A plasma processing apparatus of an embodiment of the invention is a plasma processing apparatus for effecting intended processing on a work to be processed with plasma, and particularly a plasma processing apparatus including any one of the foregoing plasma producing apparatuses.

With this plasma processing apparatus using the foregoing plasma producing apparatus, high density plasma corresponding to the number of antennas can be obtained. Therefore, the apparatus can rapidly effect the intended processing on the work with the plasma.

The plasma processing apparatus may be an apparatus utilizing plasma such as a plasma CVD apparatus, an apparatus forming a film by effecting sputtering on a sputter target in plasma, an etching apparatus using plasma, an apparatus performing ion implantation or ion doping by extracting ions from plasma, or an apparatus using the above apparatus and producing various semiconductor devices (e.g., thin-film transistors used in liquid crystal displays and others), material substrates of the semiconductor devices or the like.

The plasma producing method and apparatus and others will be described with reference to the drawings.

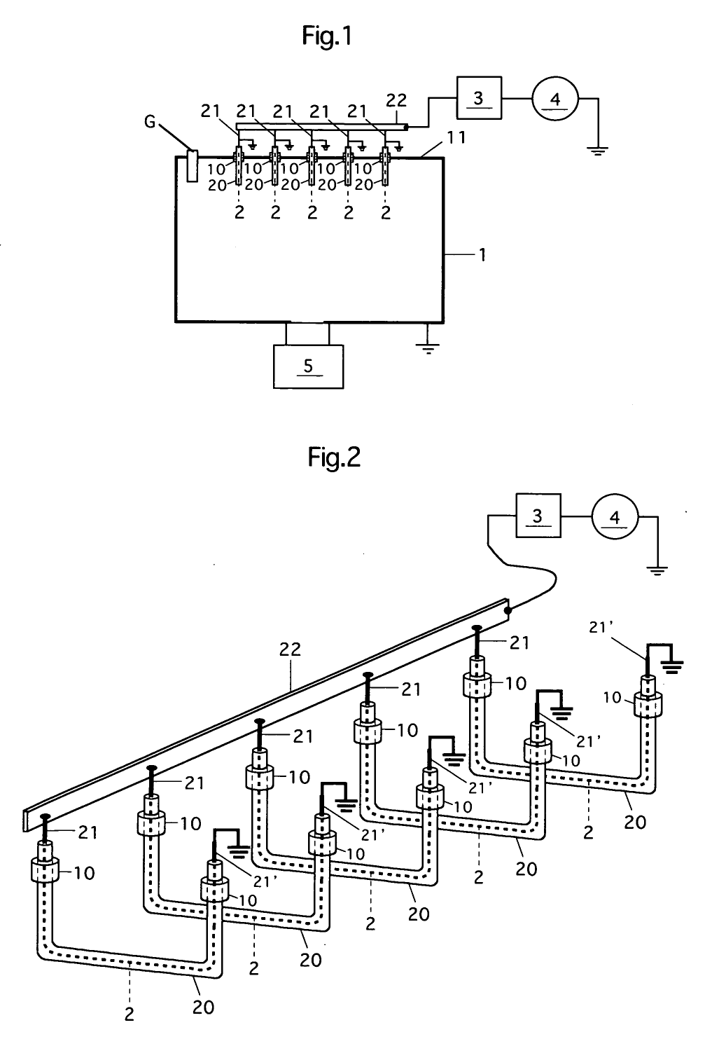

FIG. 1 shows an example of a plasma producing apparatus according to the invention. FIG. 2 is a perspective view extractively showing high-frequency antennas and others in the plasma producing apparatus in FIG. 1.

The plasma producing apparatus in FIG. 1 includes a plasma producing chamber 1. A plurality of high-frequency antennas 2 are inserted into the plasma producing chamber 1 through a top wall 11 of the chamber 1, and are arranged in the chamber 1. Each high-frequency antenna 2 is covered with an insulating member 20, and is inserted together with the electrically insulating member 20 through an electrically insulating members 10 arranged at the top wall 11.

The antennas 2 in this example have the same size, and each have a U- or substantially U-shaped form. These antennas 2 are arranged in a fashion of such parallel arrangement that the antennas successively neighbor to each other and each of the antennas is opposed to the neighboring antenna.

Each of the antennas 2 has portions 21 and 21′ projected outward from the chamber through the chamber top wall 11. One portion 21 of these portions 21 and 21′ is connected to a power supply busbar 22 common with each antenna 2. The busbar 22 is connected to a high-frequency power source 4 via a matching box 3.

In the example shown in FIGS. 1 and 2, the respective neighboring opposed antennas 2 in the chamber 1 are supplied with the high-frequency power such that these antennas 2 may have the same polarity and, in other words, these antennas 2 may be supplied with the power in the same direction, i.e., may be supplied with the currents in the same direction. The above power supply is effected on the projected portions 21 on the same side of these antennas 2.

Each antenna 2 is formed of an electrically conductive pipe. A coolant circulating device (not shown) can pass a coolant (e.g., cooling water) through the antennas for cooling them.

The conductive pipe forming the antenna in this example is made of copper, and has a circular section. However, these are not restrictive, and the antenna may be formed of a pipe made of other conductive material such as aluminum. It is not essential that the antenna is formed of a pipe, and the antenna 2 may be formed of a rod having, for example, a circular section and made of a conductive material such as copper or aluminum.

The insulating member 20 covering the antenna 2 in this example is quartz pipe. However, this is not restrictive, and the member 20 may be a pipe made of an insulating material such as alumina. The insulating member 20 may be formed of a member other than the pipe, and may be formed by coating the antenna 2 with an insulating material.

The plasma producing apparatus in FIG. 1 further includes a gas inlet portion G for passing a predetermined gas into the plasma producing chamber 1, and an exhaust device 5 for exhausting the gas from the chamber to attain a predetermined plasma production pressure in the chamber 1.

According to the plasma producing apparatus described above, the exhaust device 5 discharges the gas from the plasma producing chamber 1 to lower the chamber pressure below the predetermined plasma producing pressure, and then the predetermined gas is introduced through the gas inlet portion G into the chamber 1. While setting and maintaining the predetermined plasma producing pressure in the chamber by the exhaust device 5, a high-frequency power is supplied from the power source 4 to the antennas 2 so that inductively coupled plasma can be produced in the chamber 1.

At that time, the plurality of high-frequency antennas 2 are arranged in a fashion of such parallel arrangement that each of the antennas is opposed to the neighboring antenna, and the high-frequency power is supplied to each antenna from the terminals 21 of the antennas 2 on the same side such that electric currents flow through the antennas in the same direction. Accordingly, high density magnetic flux corresponding to the plurality of high-frequency antennas can be generated, whereby high density plasma corresponding to the plurality of high-frequency antennas can be produced.

The plasma producing apparatus described above can be used for providing various plasma processing apparatuses. For example, it is possible to provide plasma processing apparatuses such as a plasma CVD apparatus, an apparatus forming a film by effecting sputtering on a sputter target in plasma, an etching apparatus using plasma, an apparatus performing ion implantation or ion doping by extracting ions from plasma, and an apparatus using the above apparatus and producing various semiconductor devices (e.g., thin-film transistors used in liquid crystal displays and others), material substrates of the semiconductor devices or the like.

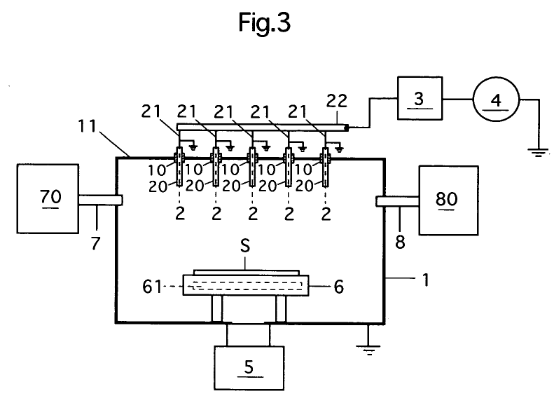

FIG. 3 shows an example of a plasma CVD apparatus using the plasma producing apparatus shown in FIG. 1. The plasma CVD apparatus in FIG. 3 differs from the plasma producing apparatus shown in FIG. 1 in that a plasma producing chamber 1 serves also as a deposition chamber, a holder 6 internally provided with a heater 61 is arranged in the chamber 1 for holding a work substrate S to be deposited thereon, gas inlet pipes 7 and 8 are employed as the gas inlet portion, the pipe 7 is connected to a monosilane gas supply device 70 and the pipe 8 is connected to a hydrogen gas supply device 80. This CVD apparatus can form a silicon thin film on the substrate S.

Substantially the same parts and same members in FIG. 3 as in the apparatus shown in FIG. 1 and FIG. 2 are indicated with the same reference numerals or symbols as in FIG. 1 and FIG. 2.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A plasma producing method in which a plurality of high-frequency antennas are arranged in a plasma producing chamber and inductively coupled plasma is generated by applying a high-frequency power from the high-frequency antennas to a gas in the plasma producing chamber, wherein at least some of the high-frequency antennas are arranged in a fashion of such parallel arrangement that the antennas successively neighbor to each other and each of the antennas is opposed to the neighboring antenna, and the high-frequency power is supplied to these high-frequency antennas from terminals of the antennas on the same side such that electric currents flow through the high-frequency antennas in the same direction.

2. The plasma producing method according to claim 1, wherein
each of the high-frequency antennas, which are arranged in a fashion of such parallel arrangement that the antennas successively neighbor to each other and each of the antennas is opposed to the neighboring antenna, is a two-dimensional structure antenna.

3. A plasma producing apparatus comprising a plasma producing chamber, a plurality of high-frequency antennas arranged in the plasma producing chamber and a high-frequency power supply device supplying a high-frequency power to the high-frequency antennas in which inductively coupled plasma is generated by applying the high-frequency power supplied from the high-frequency power supply device to a gas in the plasma producing chamber from the high-frequency antennas, wherein at least some of the high-frequency antennas are arranged in a fashion of such parallel arrangement that the antennas successively neighbor to each other and each of the antennas is opposed to the neighboring antenna, and the high-frequency power supply device supplies the high-frequency power to the high-frequency antennas, which are arranged in a fashion of such parallel arrangement that the antennas successively neighbor to each other and each of the antennas is opposed to the neighboring antenna, from terminals of the antennas on the same side such that electric currents flow through the antennas in the same direction.

4. The plasma producing apparatus according to claim 3, wherein
each of the high-frequency antennas, which are arranged in a fashion of such parallel arrangement that the antennas successively neighbor to each other and each of the antennas is opposed to the neighboring antenna, is a two-dimensional structure antenna.

5. A plasma processing apparatus for effecting intended processing on a work to be processed with plasma, comprising a plasma producing apparatus according to claim 3 or 4.
